(19) United States
(12) Patent Application Publication
(10) Pub. No.: US 2009/0130782 A1
(43) Pub. Date: May 21, 2009

(54) METHOD AND LINE FOR MANUFACTURING SEMICONDUCTOR DEVICE

(75) Inventors: Masatsugu Itahashi, Yokohama-shi (JP); Kouhei Hashimoto, Ebina-shi (JP); Nobuhiko Sato, Yokohama-shi (JP); Seiichi Tamura, Yokohama-shi (JP); Hiroshi Yuzurihara, Atsugi-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/266,725

(22) Filed: Nov. 7, 2008

(30) Foreign Application Priority Data
Nov. 19, 2007 (JP) 2007-299330

(51) Int. Cl. H01L 21/66; H01L 21/67

(52) U.S. Cl. 438/6; 29/25.01; 257/E21.53

(57) ABSTRACT

A method is provided for manufacturing a semiconductor device that includes a multilayer wiring structure in which insulating layers and wiring layers each with a plurality of conductor lines are alternately stacked on each other. The method includes steps of forming a first wiring layer on a first insulating layer, detecting a defect in the first wiring layer on the first insulating layer, and determining whether or not the defect is to be irradiated with a focused ion beam, according to a detection result. If it is determined that the defect is to be irradiated, the defect is irradiated with a focused ion beam and then a second insulating layer is formed on the first wiring layer disposed on the first insulating layer. If it is determined that the defect is not to be irradiated with a focused ion beam, the second insulating layer is formed on the first wiring layer disposed on the first insulating layer without irradiating the defect.

### BACKGROUND OF THE INVENTION

1. Field of the Invention

The present invention relates to a method and a line for manufacturing a semiconductor device, and particularly to a method and a line for wiring.

2. Description of the Related Art

A process for manufacturing a semiconductor device having a multilayer wiring structure includes steps for processing the substrate, in which transistors or the like are formed on a semiconductor wafer, and steps for processing wiring, in which insulating layers and wiring layers are formed on the semiconductor substrate having the transistors or the like formed thereon. In the steps for processing the wiring, wiring layers are formed in a multilayer structure, and subsequently inspection is performed. Japanese Patent Laid-Open No. 2005-079491 discloses a technique for repairing a defect detected in an inspection step.

In this technique, defects are repaired by photolithography, and, consequently, the manufacturing process is complicated.

Japanese Patent Laid-Open No. 11-025853 discloses a technique for repairing a defect in an electrode of a plasma display. In this technique, laser light is used to repair defects. While the minimum spot size of laser light is about 1 μm, line widths and line intervals of conductor lines of a semiconductor device are on the order of submicrons. Accordingly, although the defect may be repaired, conductor lines adjacent to the defect are damaged undesirably. In addition, part of the defect may remain, depending on the material, because defect repair using laser light fuses and sublimates the material due to heat. Furthermore, laser light can damage a conductor line, an insulating layer, or a semiconductor region under the defect, because the insulating layers of a multilayer wiring structure transmit laser light.

### SUMMARY OF THE INVENTION

The present invention, in an embodiment, provides a method for manufacturing a semiconductor device in which a defect can be repaired while preventing damage to normal conductor lines.

According to an aspect of the invention, a method for manufacturing a semiconductor device having a multilayer wiring structure is provided, in which insulating layers and at least one wiring layer including a plurality of conductor lines are alternately stacked on each other. The method includes a step of forming one of the wiring layers on a first insulating layer, a step of detecting a defect in the wiring layer on the first insulating layer, and a step of determining whether or not the defect is to be irradiated with an focused ion beam, according to a result of the step of detecting a defect. If it is determined that the defect is to be irradiated, the defect is irradiated with a focused ion beam and then a second insulating layer is formed on the wiring layer disposed on the first insulating layer. If it is determined that the defect is not to be irradiated with a focused ion beam, the second insulating layer is formed on the wiring layer disposed on the first insulating layer without irradiating the defect with a focused ion beam.

According to another aspect of the invention, a manufacturing line is provided for manufacturing a semiconductor device having a multilayer wiring structure, in which insulating layers and at least one wiring layer including a plurality of conductor lines are alternately stacked on each other. The manufacturing line includes at least one apparatus configured to form one of the wiring layers on a first insulating layer, detect a defect in the wiring layer disposed on the first insulating layer, repair the defect by irradiating the defect with a focused ion beam, and form a second insulating layer on the wiring layer disposed on the first insulating layer after the defect is repaired.

In the method and the line for manufacturing a semiconductor device, defects can be repaired without damaging normal conductor lines.

Other features and advantages of various embodiments of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a flow diagram of a process according to a first embodiment of the present invention.

FIGS. 2A to 2E are sectional views of a semiconductor device according to the first embodiment.

FIG. 3 is a schematic plan view for representing a defect.

FIGS. 4A and 4B are schematic plan representations of scattered matter.

The accompanying drawings, which are incorporated in and constitute a part of the specification, illustrate embodiments of the invention and, together with the description, serve to explain the principles of the embodiments of the invention.

### DESCRIPTION OF THE EMBODIMENTS

A method for manufacturing a semiconductor device according to an embodiment of the present invention includes a step of detecting whether or not a defect is present in a specific wiring layer in a multilayer wiring structure, after the wiring layer is formed, and a step of irradiating the defect with a focused ion beam (hereinafter referred to as FIB) if a defect exists. The defect is thus repaired, and then an insulating layer and subsequently another wiring layer are formed in that order over the wiring layer whose defect has been repaired. This semiconductor device manufacturing method repairs defects across regions between the conductor lines while preventing damage to normal conductor lines.

The defect mentioned herein refers to a short-circuited portion disposed across a region between conductor lines and affecting the operation of the semiconductor device. Such a defect may be, for example, a short-circuited portion that is not present in the photomask pattern used to form the conductor lines, or it may be a region that is be treated so as not to be short-circuited or connected. More specifically, the defect may refer to a short-circuited portion that is not developed (i.e., not removed) and is thus left in a mask pattern region due to a fine pattern formed at narrow intervals of the resolution limit in that mask pattern region, or it may refer to a short-circuited or connected portion produced in a region on which ion beam drawing or etching will be performed for fine working to create openings in the portion.

In the description, a semiconductor substrate used as a material is expressed as a “substrate”, and the term substrate may also refer to the resulting material that has been worked. For example, the substrate used herein may refer to a member on which at least one semiconductor region or the like has been formed, a member in the course of a series of manufacturing steps, or a member after the completion of the series of manufacturing steps. The multilayer wiring structure includes alternately stacked wiring layers and insulating layers and is disposed on the substrate. Each wiring layer has a plurality of conductor lines formed on an insulating layer. The plurality of conductor lines can be electrically controlled separately from each other. The conductor lines are formed in an electroconductive pattern made of aluminum or copper. The pattern may serve as a light shield. A set of conductor lines may be referred to as a wiring pattern. The manufacturing line of the semiconductor device includes at least one apparatus for performing a plurality of steps.

Embodiments of the invention will now be described with reference to the drawings.

### First Embodiment

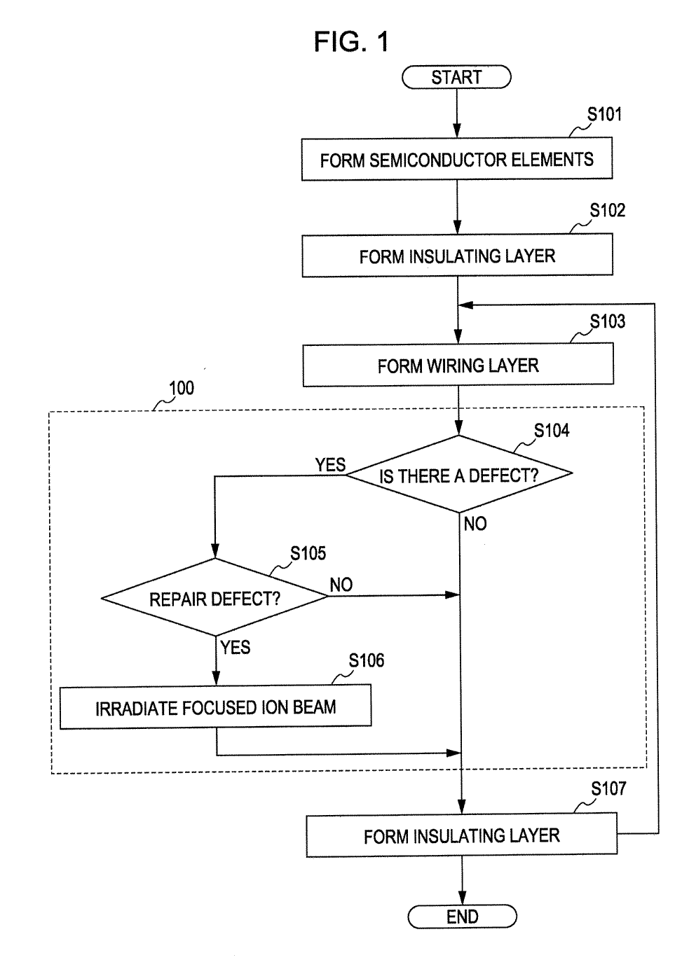

A method for manufacturing a semiconductor device according to a first embodiment will now be described with reference to FIG. 1. FIG. 1 is a flow chart of the semiconductor manufacturing method.

First, transistors and other semiconductor elements are formed on a semiconductor substrate in Step S101, and then a first insulating layer is formed on the semiconductor substrate in Step S102. Subsequently, in Step S103, a first wiring layer including a plurality of conductor lines is formed on the first insulating layer. After Step S103, a defect inspection is performed to detect whether or not a defect is present (Step S104). At Step S104, if a defect is not detected, the manufacturing process is continued at Step S107. In contrast, if a defect is detected at Step S104, whether or not the defect will be repaired is determined (Step S105). If yes, for repairing the defect, the defect is irradiated with an FIB (Step S106). If it is determined that the defect is not to be repaired, the defect is not irradiated with a FIG and the manufacturing process is continued at Step S107. In addition, the address of the defect is recorded so that the location of the defect can be identified in a subsequent step. The address of the defect may be recorded in the defect detection step (Step S104).

Then, a second insulating layer is formed on the first wiring layer in Step S107. Subsequently, another wiring layer is formed on the second insulating layer. The formation of the wiring layer and the insulating layer is repeated according to the number of wiring layers desired. After forming an uppermost wiring layer, a protective layer is formed to complete the series of steps for wiring.

Although the above description illustrates the case in which the first wiring layer is subjected to defect repair, the same steps for defect repair (Steps S104 to S106 surrounded by a dotted line 100) can be applied after the formation of the second insulating layer. The steps for defect repair (S104 to S106) may be applied to at least one wiring layer, and the process may be completed after forming the insulating layer in Step S107 without forming another wiring layer.

A manufacturing line for performing the above-describe steps includes apparatuses for forming the semiconductor elements, the insulating layers, and the wiring layers, a defect inspection apparatus, and a focused ion beam apparatus. The apparatuses for forming the semiconductor elements, the insulating layers, and the wiring layers include known apparatuses, such as an ion implantation apparatus, a CVD apparatus, and a cleaning apparatus, for example. In addition to these apparatuses, the manufacturing line may include a defect inspection apparatus and a focused ion beam apparatus.

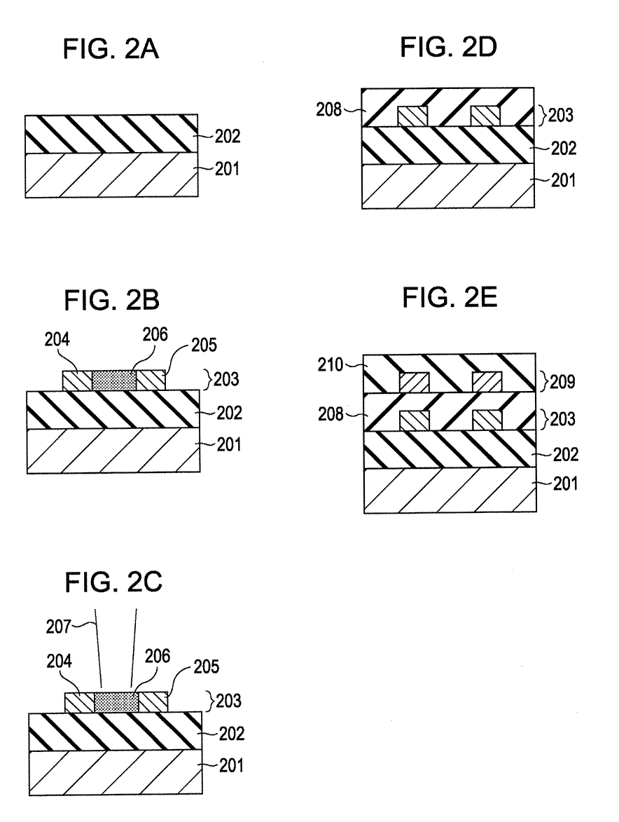

The manufacturing method of the embodiment shown in FIG. 1 will be further described in detail with reference to FIGS. 2A to 2E, which are sectional views of a semiconductor device including a multilayer wiring structure. FIGS. 2A to 2E are enlarged sectional views of a semiconductor substrate on which a plurality of chips may be disposed, schematically showing a section of one of the chips or a semiconductor device. FIGS. 2A to 2E omit semiconductor elements, contact plugs, and so forth.

FIG. 2A shows a silicon semiconductor substrate 201 and a first insulating layer 202 made of silicon oxide. Semiconductor elements are formed on the substrate 201, and the first insulating layer 202 is formed over the substrate 201 (Steps S101 and S102 in FIG. 1). After forming the first insulating layer 202, contact plugs are formed as required.

Then, a first wiring layer 203 is formed on the first insulating layer 202, as shown in FIG. 2B (Step S103 in FIG. 1). More specifically, for example, an electroconductive layer, such as an aluminum layer, is formed on the first insulating layer 202 and the contact plugs, and is then patterned into conductor lines in desired shapes by photolithography. In FIG. 2B, reference numerals 204 and 205 designate the conductor lines having desired shapes, and reference numeral 206 designates a defect.

Defect inspection is performed to detect a defect (Step S104). In Step S104, a defect is detected with, for example, a bright field optical inspection apparatus. More specifically, an image of the wiring pattern is compared with an image of the desired pattern for each semiconductor device, or for each unit cell of repetitive patterns, if the semiconductor device includes repetitive patterns to thus detect a defect. If a defect is detected, data outputted from the defect inspection apparatus includes the coordinates and the size of the defect. If the defect inspection apparatus is capable of automatic defect classification (ADC), the data includes the type of defect. The defect inspection apparatus is not limited to the bright-field optical type, and may be a dark-field type or a laser scattering type inspection apparatus.

It is determined whether the detected defect is to be repaired or not according to the data from the defect inspection apparatus or ADC. This determination may be made by the defect inspection apparatus, or by another apparatus for determining whether or not the defect is to be repaired.

Determination of whether or not the defect is to be repaired will now be described. The reason why the determination of whether or not the defect is to be repaired is made is that all defects cannot be repaired, and that even if a defect can be repaired, it may take a long time to repair the defect. Predetermined values are assigned to the obtained defect data, such as the type, the number, and the size of the defect, and a determination of whether or not the defect is to be repaired is made. For example, if a defect extends across three or more conductor lines, or if three or more defects are present in one chip, a determination may be made that such defects are not to be repaired. Such criteria may be set for a type of data or for a plurality of types of data.

The data used for the determination of whether or not a defect is to be repaired may be obtained by observation through an SEM (scanning electron microscope) after a defect has been detected. Alternatively, defect images may be automatically obtained using an automatic defect review system and the determination may be made according to an observation of each image. SEM observation of detected defects allows proper identification of the type, the size, and the shape of the defects. If a defect (e.g., the defect 206) is to be repaired, an FIB irradiation region (where an FIB is irradiated) is determined. Then, the defect 206 is irradiated with the FIB 207 as shown in FIG. 2C (Step S106). The ion beam sputters the metal of the defect and, thus, the defect 206 is repaired through removal of the metal by sputtering or etching the metal away. More specifically, the defect 206 across a region between the first conductor line 204 and the second conductor line 205 can be removed. For example, for an aluminum-based wiring pattern including a titanium nitride barrier metal layer, an FIB irradiation is performed under the following conditions. A defect in, for example, a wiring pattern including a copper-aluminum layer of 400 nm in thickness and a titanium nitride layer of 50 nm in thickness can be irradiated with a gallium FIB at a dose of 1.2×10^{˜}cm⁻² at an acceleration voltage of 30 kV.

An FIB/SEM combined system including an SEM or TEM is preferably used as the FIB apparatus. The FIB/SEM combined system can alternately repeat SEM observation and FIB irradiation of the substrate placed in a vacuum in the same apparatus. In such a system, the substrate is placed in a vacuum during SEM observation and FIB irradiation and a waiting time is not required between the two operations. Consequently, productivity is increased.

Then, a second insulating layer 208 is formed on the wiring layer 203, after determining that the defect is not to be repaired or after FIB irradiation if the defect is to be repaired (FIG. 2D). Furthermore, a second wiring layer 209 is formed and then a third insulating layer 210 is formed after the steps of defect inspection and FIB irradiation, as shown in FIG. 2E. Thus, a multilayer wiring structure may be completed.

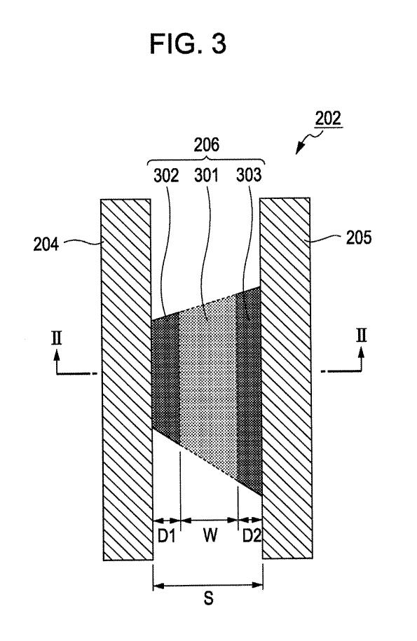

The step of irradiating a defect with an FIB will now be described in detail with reference to FIG. 3. FIG. 3 schematically shows a defect that has been detected and then has been determined to be repaired. The section taken along line II-II in FIG. 3 is shown in FIGS. 2A to 2E, and the same parts as in FIGS. 2A to 2E are designated by the same reference numerals.

Preferably, the FIB irradiation region (where an FIB is irradiated onto) is determined in consideration of not only removing the defect present across the region between conductor lines, that is, a short-circuited portion between the conductor lines, but also in consideration of preventing damage to the conductor lines. More specifically, it is preferable that the width of the region to be removed be smaller than the interval between the conductor lines. It is difficult to have the region actually irradiated with an FIB coincident fully with an intended FIB irradiation region, and a slight displacement usually occurs between the intended FIB irradiation region and the actual irradiation region. If the line width of and the interval between the conductor lines are, for example, 1 μm or more, the displacement may be insignificant. For a wiring pattern having conductor lines having line widths and line intervals on the order of submicrons, however, a small displacement may cause a conductor line to be damaged. Even if a conductor line is damaged at the surface, it does not always result in a failure, such as an electrical break. Since the cross section of a damaged conductor line is reduced, however, a current may flow at a high density through a damaged conductor line. By reducing the width of the region to be removed to a level smaller than the line interval of the conductor lines, damage to the conductor lines can be reduced.

The step shown in FIG. 3 will further be described. Let the interval between the first conductor line 204 and the second conductor line 205 be S and let the width of a portion 301 of the defect 206 to be removed be W. The portions 302 and 303 of the defect 206 are left after FIB irradiation. By determining the FIB irradiation region so as to satisfy the relationship W<S, damage to the conductor lines 204 and 205 can be prevented even if a displacement occurs between the actual irradiation region and the intended irradiation region. Also, by setting the distances between the FIB irradiation region and the conductor lines 204 and 205 to a level larger than the maximum displacement of FIB irradiation, damage to the conductor lines 204 and 205, which should normally be formed, can be prevented.

FIB irradiation will further be described. For the sake of simplicity, let the FIB irradiation region be designated by reference numeral 301 even though the FIB irradiation region does not always coincide with the portion of the defect to be removed. Let the distances between the FIB irradiation region 301 and the first conductor line 204 and between the FIB irradiation region 301 and the second conductor line 205 be D1 and D2, respectively. Let the maximum displacement from the intended FIB irradiation region be estimated at Δd. If the FIB irradiation region is determined so as to satisfy the relationships D1>Δd and D2>Δd, the defect can be removed without damaging the conductor lines 204 and 205 even if the FIB irradiation region is displaced to the left side or to the right side. More specifically, when, for example, the maximum displacement of an FIB irradiation region is 0.15 μm, the FIB irradiation region 301 can be determined so as to satisfy the relationships D1>0.15 μm and D2>0.15 μm.

If the FIB irradiation region 301 is displaced in a vertical direction, the defect may remain and the conductor lines 204 and 205 are not repaired, even though the displacement does not affect the conductor lines 204 and 205. In such a case, a series of steps for defect inspection can be repeated after FIB irradiation. Alternatively, the defect image may be observed with an SEM after FIB irradiation and then an FIB may be irradiated again. A series of these steps may be repeated until the defect is completely repaired.

Then, other wiring patterns or other layers may be formed, if necessary, and finally the resulting semiconductor substrate is diced into semiconductor devices. At this point, the semiconductor devices whose defects are not repaired because of the presence of too many defects are separated out according to the recorded addresses. If defects occur continuously at the same address, the apparatus may be determined to be out of order. Such an apparatus can be maintained or repaired.

The semiconductor device manufacturing method according to the present embodiment is advantageously applied to semiconductor devices in which a redundancy circuit cannot be provided or semiconductor devices having a large chip area. The method of the present embodiment is particularly advantageous to image pickup devices including a photoelectric transducer, such as a MOS image pickup device, because such an image pickup device has many conductor lines and a large chip area and does not allow the use of a redundancy circuit. The techniques for detecting defects and for determining whether or not a defect is to be repaired are not limited to the above. For example, SEM observation may be omitted.

### Second Embodiment

A method for manufacturing a semiconductor device according to a second embodiment includes a step of removing scattered matter and a step of cleaning in addition to the steps of the method according to the first embodiment. More specifically, the step of removing scattered matter and the step of cleaning are performed between Step S106 of irradiating a defect with an FIB and Step S107 of forming the second insulating layer. These additional steps enhance the reliability of defect repair to increase yield.

Scattered matter produced by Step S106 will now be described. In the step of irradiating an FIB for repairing a defect, the defective portion is removed by the sputtering effect. At this point, the removed defective portion is scattered into a state of fine particles (scattered matter). The scattered matter is sucked away to some extent by a pump installed in an SEM apparatus or an FIB apparatus for evacuating the chamber. However, the scattered matter cannot be removed completely from the chamber. Consequently, the scattered matter may be deposited around the region irradiated with an FIB and remain as a defect.

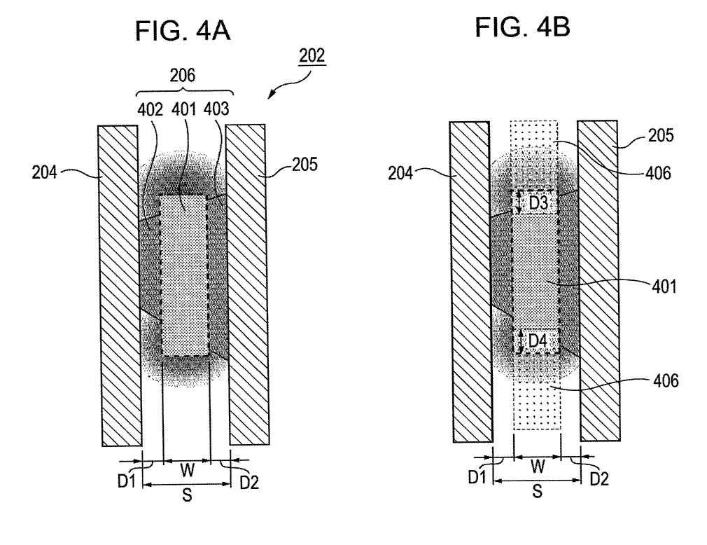

FIG. 4A shows how the scattered matter may be distributed on a semiconductor device. FIG. 4A is a representation based on the results of an analysis for the distribution of scattered matter performed with an energy dispersive X-ray spectrometer (EDX) after FIB irradiation of a defect. In FIG. 4A, the same parts as in FIG. 3 are designated by the same reference numerals and the descriptions thereof will not be repeated. The region designated by reference numeral 401 is an FIB irradiation region, and the regions designated by reference numerals 402 and 403 are portions of a defect remaining after FIB irradiation. The shape of the FIB irradiation region 401 is different from the FIB irradiation region 301 shown in FIG. 3. The FIB irradiation region can take a desired shape. The distribution of the scattered matter produced by FIB irradiation is represented by shades of gray. The darker the shading, the larger the amount of scattered matter. The region around the irradiation region 401 is darker. Hence, FIG. 4A shows that a large amount of scattered matter is present around the FIB irradiation region 401 between the conductor lines 204 and 205. As the distance from the defect is increased, the amount of scattered matter is reduced. The amount of scattered matter deposited in the FIB irradiation region 401 is much smaller than that in the region adjacent to the FIB irradiation region 401, and the scattered matter in the FIB irradiation region is not often considered to be a defect.

The region to be irradiated with an FIB in the step of removing scattered matter (reirradiation region) is determined, taking into account the result of the scattered matter distribution. Turning now to FIG. 4B, the same parts as in FIGS. 3 and 4A are designated by the same reference numerals and the descriptions thereof will not be repeated.

In FIG. 4B, the regions designated by reference numerals 405 and 406 are regions to be reirradiated with an FIB. The width of the reirradiation region in the direction of the line interval is set so that D1 and D2 are larger than the maximum displacement Δd of IFB irradiation, as in the determination of the irradiation region 401. The length of the reirradiation region in the direction perpendicular to the line interval direction is set so as to overlap the irradiation region 401. The overlaps are represented by D3 and D4, and are larger than the maximum displacement Δd of the FIB irradiation. The overlaps ensure that the region adjacent to the defect onto which the largest amount of scattered matter is deposited (region adjacent to the FIB irradiation region 401) becomes electrically isolated after reirradiation.

The conditions of FIB reirradiation will now be described. For example, a 400 nm thick aluminum-based wiring pattern including a 50 nm thick titanium nitride barrier metal layer, as described in connection with the first embodiment, is treated. First, the FIB irradiation in Step S106 is performed using gallium ions at a dose of 1.2×10¹⁸ cm⁻² at an acceleration voltage of 30 kV. Then, FIB reirradiation is performed using gallium ions at a dose of 1.2×10¹⁷ cm⁻² (reduced by 10%) at an acceleration voltage of 30 kV. Preferably, the dose and the acceleration voltage of FIB reirradiation are reduced from those of the FIB irradiation for removing the defect. Because the thickness per unit area of the scattered matter is smaller than that of the wiring layer, damage to the insulating layer can be prevented by reducing the dose or the acceleration voltage to reduce the energy of the FIB during reirradiation.

The scattered matter is extremely small, and cannot be observed by SEM. Accordingly, where the scattered matter is present is determined by EDX. However, how the scattered matter produced by irradiating the defect with an FIB is deposited can be estimated from, for example, the height of the wiring layer and the energy of the FIB. Regions where the scattered matter can be deposited can be stored in a database, and EDX analysis may be omitted.

After FIB reirradiation, a cleaning step is performed to remove scattered matter not considered to be a defect or scattered matter deposited on the conductor lines. For the cleaning step, for example, pure water or a resist remover that does not damage the conductor lines can be used as a cleaning liquid. By performing the cleaning step, the defect repair efficiency can be increased. In addition, the cleaning step can prevent the scattered matter from contaminating the semiconductor manufacturing apparatus or foreign matter from appearing in a subsequent step.

The FIB reirradiation step and the cleaning step are not necessarily performed in that order. Even if either the FIB reirradiation or the cleaning step is performed, the defect repair efficiency can be increased.

### Third Embodiment

The multilayer structure of wiring patterns used in the first embodiment and the second embodiment will now be described in detail. In a wiring pattern on the order of submicrons, the current density of the current flowing through conductor lines is increased. Accordingly, it is desirable that the electromigration resistance be enhanced. In order to enhance the electromigration resistance of aluminum-based conductor lines, a technique has been known in which a transition metal, such as copper is added to aluminum. Alternatively, a layer of a refractory metal, such as titanium or titanium nitride, may be formed on an aluminum pattern. In the present embodiment, the wiring pattern has a multilayer structure including titanium nitride layers with an aluminum layer in between.

When a defect in a wiring pattern containing such a refractory metal is repaired, the technique for repairing the defect by irradiating laser light to fuse and sublimate the material of the wiring pattern, as disclosed in Japanese Patent Laid-Open No. 11-025853, may cause a residue to remain on part of the defect. On the other hand, in the method described in the first embodiment, an FIB is irradiated. Because the physical energy of an ion beam is used, the defect can be completely removed. Thus, an FIB is preferably used for repairing a defect in a wiring structure containing a refractory metal. It goes without saying that an FIB can be used for wiring structures not containing a refractory metal. Even if the wiring layers are formed in a lower position, damage to conductor lines formed in a lower layer can be prevented because the ion beam energy is absorbed by the insulating layer. Thus, FIBs are suitable for removing defects in a multilayer wiring structure.

Although in the embodiments, titanium nitride is used as a material containing a refractory metal, other refractory metals can be used, such as tantalum and tungsten, and a silicide of a refractory metal may be used instead of the nitride. Also, the electric conductor may be made of polysilicon or copper, instead of an aluminum-based material.

Although the present invention has been described with reference to exemplary embodiments, it is to be understood that the invention is not limited to the disclosed exemplary embodiments. The scope of the following claims is to be accorded the broadest interpretation so as to encompass all modifications and equivalent structures and functions.

This application claims the benefit of Japanese Application No. 2007-299330 filed Nov. 19, 2007, which is hereby incorporated by reference herein in its entirety.

What is claimed is:

1. A method for manufacturing a semiconductor device that includes a multilayer wiring structure in which insulating layers and at least one wiring layer with a plurality of conductor lines are alternately stacked on each other, the method comprising steps of:
forming a first wiring layer on a first insulating layer;
detecting a defect in the first wiring layer on the first insulating layer;
determining whether or not the defect is to be irradiated with a focused ion beam, according to a result of the detecting step;
if it is determined that the defect is to be irradiated with the focused ion beam, irradiating the defect with the focused ion beam and then forming a second insulating layer on the first wiring layer disposed on the first insulating layer; and
if it is determined that the defect is not to be irradiated with the focused ion beam, forming the second insulating layer on the first wiring layer disposed on the first insulating layer without irradiating the defect with the focused ion beam.

2. The method according to claim 1, wherein the step of determining whether or not the defect is to be irradiated with the focused ion beam and the step of irradiating the defect with the focused ion beam are performed in a same apparatus.

3. The method according to claim 1, wherein the first wiring layer disposed on the first insulating layer has at least a first conductor line and a second conductor line with an interval therebetween, and wherein, if the defect is present across the interval between the first conductor line and the second conductor line, the step of irradiating the defect with the focused ion beam is performed by irradiating the focused ion beam onto a region between the first conductor line and the second conductor line having a width smaller than the interval between the first conductor line and the second conductor line.

4. The method according to claim 3, wherein the region irradiated with the focused ion beam is apart from the first conductor line or the second conductor line by more than a maximum displacement of the focused ion beam.

5. The method according to claim 1, further comprising a step of forming a second wiring layer on the second insulating layer.

6. The method according to claim 1, wherein, in the step of irradiating the defect with the focused ion beam, the focused ion beam is irradiated at least twice continuously.

7. The method according to claim 6, wherein the second irradiation of the focused ion beam is applied to a larger area than the first irradiation, at a lower intensity than the first irradiation.

8. The method according to claim 1, further comprising a step of cleaning a surface irradiated with the focused ion beam between the step of irradiating the focused ion beam and the step of forming the second insulating layer.

9. The method according to claim 1, wherein the semiconductor device is a MOS sensor.

10. A manufacturing line for manufacturing a semiconductor device that includes a multilayer wiring structure in which insulating layers and at least one wiring layer with a plurality of conductor lines are alternately stacked on each other, the manufacturing line comprising at least one apparatus that performs functions of:
forming a first wiring layer on a first insulating layer;
detecting a defect in the first wiring layer disposed on the first insulating layer;
repairing the defect by irradiating the defect with a focused ion beam; and
forming a second insulating layer on the first wiring layer disposed on the first insulating layer after the defect is repaired.
